(19) United States
(12) Patent Application Publication
(10) Pub. No.: US 2006/0198206 A1
(43) Pub. Date: Sep. 7, 2006

(54) Semiconductor device and inspection method of the same and electromagnetic detection equipment

(75) Inventor: Satoshi Mishima, Kobe-shi (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/349,981

(22) Filed: Feb. 9, 2006

(30) Foreign Application Priority Data
Feb. 21, 2005 (JP) 2005-043293

(51) Int. Cl. G11C 7/10

(52) U.S. Cl. 365/189.01

(57) ABSTRACT

A heat detection equipment as electromagnetic detection equipment is combined with a semiconductor integrated circuit including, without setting an extra external test terminal, a control circuit for outputting chip information and resistors driven for generating thermal energy that is a kind of electromagnetic waves to obtain manufacturing information and inspection information in a contactless manner, so that a system thus configured operate in synchronization with an automated test equipment (ATM). Consequently, in an actual semiconductor integrated circuit, it is possible to improve quality while achieving security.

### FIELD OF THE INVENTION

The present invention relates to ease of inspection of a semiconductor integrated circuit having a reduced number of pins and higher security.

### BACKGROUND OF THE INVENTION

In semiconductor integrated circuits which are reduced in the number of pins and increased in security in view of a limitation on the number of pins, a chip size, security and so on, test circuits are hard to mount and thus inspection information has become hard to obtain year by year.

In a conventional inspection method, in order to confirm a degree of perfection of a semiconductor integrated circuit at an actual product level, a unit is provided for obtaining inspection information in additional semiconductor integrated circuit designed before commercialization. Alternatively, in general, an input/output terminal only for tests is provided, a mode only for tests is provided, and a unit is provided for serially outputting inspection information on test results of boundary scan tests or the like.

In order to locate an actual faulty part, various contents of defects can be accurately captured by analyzers such as a thermo tracer and an emission microscope which capture heat generation and light emission. As semiconductor devices become complicated, it has become more difficult to specify the contents of defects. Thus, emission microscopes and LSI testers as ATS (Automated Test Equipment) are connected to each other in some systems.

[Patent Document 1] Japanese Patent Publication No. 6-87476 (FIG. 1)

[Patent Document 2] Japanese Patent Laid-Open No. 2000-311929 (FIG. 1)

[Non-patent Document 1] A diagnosis method of an integrated circuit, emission microscope vendor website, etc., Independent Administrative Institution RIKEN, “Development of Diagnosis Method of Integrated Circuit using Terahertz Wave Emission” [retrieved on Sep. 1, 2004], Internet <URL: http://www.riken.go.jp/r-world/info/release/press/2004/04 0122_{—}2/>.

In the future, however, it is expected that semiconductor integrated circuits with a reduced number pins and higher security will be more desired. As semiconductor devices become complicated, problems are expected to occur. For example, chip information may not be obtained, or even when a scan circuit can be mounted, it takes a long time to obtain chip information. Further, in view of security, concerns are rising that an external output port may increase danger.

An object of the present invention is not to specify an image of an actual faulty part but to provide a semiconductor integrated circuit and an inspection method thereof which can improve the quality of the semiconductor integrated circuit while achieving security without setting an extra external test terminal.

### DISCLOSURE OF THE INVENTION

A semiconductor integrated circuit according to the first aspect of the present invention comprises a semiconductor substrate, a control circuit mounted on said semiconductor substrate and activated by a predetermined input signal, and elements mounted on said semiconductor substrate and outputting chip information as electromagnetic waves in response to an output of the control circuit.

A semiconductor integrated circuit according to the second aspect of the present invention is the semiconductor integrated circuit of the first aspect, wherein the chip information is manufacturing information or test information.

A semiconductor integrated circuit according to the third aspect of the present invention is the semiconductor integrated circuit of the first aspect, wherein the elements are arranged in a one-dimensional manner or two-dimensional manner.

A semiconductor integrated circuit according to the fourth aspect of the present invention is the semiconductor integrated circuit of the first aspect, wherein each element has a variable output.

A semiconductor integrated circuit according to the fifth aspect of the present invention is the semiconductor integrated circuit of the first aspect, wherein the electromagnetic waves are outputted a plurality of times by activating the control circuit.

A semiconductor integrated circuit according to the sixth aspect of the present invention is the semiconductor integrated circuit of the first aspect, wherein when the control circuit is in an inactive state, the elements are in a given output state.

A semiconductor integrated circuit according to the seventh aspect of the present invention is the semiconductor integrated circuit of the first aspect, wherein when the control circuit is in an inactive state, the elements are in a given output state, and all the elements are selected and the electromagnetic waves are outputted in the given output state.

A semiconductor integrated circuit according to the eighth aspect of the present invention is the semiconductor integrated circuit of the first aspect, wherein when the control circuit is in an inactive state, the elements are in a given output state, and all the elements are selected but no electromagnetic waves are outputted in the given output state.

A semiconductor integrated circuit according to the ninth aspect of the present invention is the semiconductor integrated circuit of the first aspect, and further comprises a fuse connected in series with the elements, the fuse being disconnected after the chip information is outputted.

A semiconductor integrated circuit according to the tenth aspect of the present invention is the semiconductor integrated circuit of the first aspect, and further comprises nonvolatile memory connected in series with the elements, the nonvolatile memory having data brought into a non-output state after the chip information is outputted.

An electromagnetic detection equipment according to the eleventh aspect of the present invention is used for reading of a semiconductor integrated circuit for outputting chip information as electromagnetic waves, the electromagnetic detection equip comprising an electromagnetic device section for capturing electromagnetic waves from the semiconductor integrated circuit, and a processing section for performing data conversion on information having been detected by the electromagnetic device section and obtaining chip information.

An electromagnetic detection equipment according to the twelfth aspect of the present invention is the electromagnetic detection equipment of the eleventh aspect, further comprising an optical device section for capturing thermal energy from the semiconductor integrated circuit as infrared light, and a processing section for performing data conversion on information having been detected by the optical device section and obtaining chip information.

An electromagnetic detection equipment according to the thirteenth aspect of the present invention is the electromagnetic detection equipment of the eleventh aspect, further comprising an optical device section for capturing light emission from the semiconductor integrated circuit, and a processing section for performing data conversion on information having been received in the optical device section and obtaining chip information.

An electromagnetic detection equipment according to the fourteenth aspect of the present invention is the electromagnetic detection equipment of the eleventh aspect, further comprising a magnetic field detection device section for capturing a magnetic line of force from the semiconductor integrated circuit, and a processing section for performing data conversion on information having been detected in the magnetic field detection device section and obtaining chip information.

An inspection method of a semiconductor integrated circuit according to the fifteenth aspect of the present invention comprises operating the heat detection equipment of the eleventh aspect and an ATE (Automated Test Equipment) simultaneously, and analyzing or inspecting, by means of the ATE, chip information having been read by the detection equipment.

An inspection method of a semiconductor integrated circuit according to the sixteenth aspect of the present invention is the method of the of the fifteenth aspect, further comprising controlling a processing flow based on the chip information.

An inspection method of the semiconductor integrated circuit according to the seventeenth aspect of the present invention is the inspection method of the fifteenth aspect, wherein the electromagnetic detection equipment is a heat detection equipment for reading of a semiconductor integrated circuit for outputting chip information as thermal energy, and the method further comprises operating the heat detection equipment and the ATE simultaneously, and analyzing, by means of the ATE, chip information having been read by the heat detection equipment.

An inspection method of a semiconductor integrated circuit according to the eighteenth aspect of the present invention is the inspection method of the fifteenth aspect, wherein the electromagnetic detection equipment is a light detection equipment for reading of a semiconductor integrated circuit for outputting chip information as an optical signal, and the method further comprises operating the light detection equipment and the ATE simultaneously, and analyzing, by means of the ATE, chip information having been read by the light detection equipment.

An inspection method of the semiconductor integrated circuit according to the nineteenth aspect of the present invention is the inspection method of the fifteenth aspect, wherein the electromagnetic detection equipment is a magnetic field detection equipment for reading of a semiconductor integrated circuit for outputting chip information as a magnetic line of force, and the method further comprises operating the magnetic field detection equipment and the ATE simultaneously, and analyzing, by means of the ATE, chip information having been read by the magnetic field detection equipment.

An inspection method of a semiconductor integrated circuit according to the twentieth aspect of the present invention is a method for inspecting a semiconductor integrated circuit including a semiconductor substrate mounted with a control circuit activated by a predetermined input signal, elements for outputting chip information as electromagnetic waves in response to an output of the control circuit, and a fuse connected in series with the elements, wherein the method comprises: simultaneously operating an ATE and an electromagnetic detection equipment including an electromagnetic device section for capturing magnetic waves from the semiconductor integrated circuit, and a processing section for performing data conversion on information having been detected in the electromagnetic device section and obtaining chip information; and disconnecting the fuse in an inspection process before shipment.

An inspection method of a semiconductor integrated circuit according to the twenty-first aspect of the present invention is a method for inspecting a semiconductor integrated circuit including a semiconductor substrate mounted with a control circuit activated by a predetermined input signal, elements for outputting chip information as electromagnetic waves in response to an output of the control circuit, and a nonvolatile memory connected in series with the elements, wherein the method comprises: simultaneously operating an ATE and an electromagnetic detection equipment including an electromagnetic device section for capturing magnetic waves from the semiconductor integrated circuit, and a processing section for performing data conversion on information having been detected in the electromagnetic device section and obtaining chip information; and bringing data of the nonvolatile memory having data into a non-output state in an inspection process before shipment.

An inspection method of a semiconductor integrated circuit according to the twenty-second aspect of the present invention is a method for inspecting a semiconductor integrated circuit including a semiconductor substrate mounted with a control circuit activated by a predetermined input signal, elements for outputting chip information as electromagnetic waves in response to an output of the control circuit, and a nonvolatile memory connected in series with the elements, wherein the method comprises: simultaneously operating an ATE and an electromagnetic detection equipment including an electromagnetic device section for capturing magnetic waves from the semiconductor integrated circuit, and a processing section for performing data conversion on information having been detected in the electromagnetic device section and obtaining chip information; bringing data of the nonvolatile memory having data into a non-output state in an inspection process before shipment; and rewriting the nonvolatile memory into a connecting state again to output the chip information again.

An inspection method of a semiconductor integrated circuit according to the twenty-third aspect of the present invention is the method of the twentieth aspect, wherein the electromagnetic detection equipment is a heat detection equipment used for reading of a semiconductor integrated circuit for outputting chip information as thermal energy.

An inspection method of a semiconductor integrated circuit according to the twenty-fourth aspect of the present invention is the method of the twenty-first aspect, wherein the electromagnetic detection equipment is a heat detection equipment used for reading of a semiconductor integrated circuit for outputting chip information as thermal energy.

An inspection method of a semiconductor integrated circuit according to the twenty-fifth aspect of the present invention is the method of the twenty-second aspect, wherein the electromagnetic detection equipment is a heat detection equipment used for reading of a semiconductor integrated circuit for outputting chip information as thermal energy.

An inspection method of a semiconductor integrated circuit according to the twenty-sixth aspect of the present invention is the method of the twentieth aspect, wherein the electromagnetic detection equipment is a light detection equipment used for reading of a semiconductor integrated circuit for outputting chip information as an optical signal.

An inspection method of a semiconductor integrated circuit according to the twenty-seventh aspect of the present invention is the method of the twenty-first aspect, wherein the electromagnetic detection equipment is a light detection equipment used for reading of a semiconductor integrated circuit for outputting chip information as an optical signal.

An inspection method of a semiconductor integrated circuit according to the twenty-eighth aspect of the present invention is the method of the twenty-second aspect, wherein the electromagnetic detection equipment is a light detection equipment used for reading of a semiconductor integrated circuit for outputting chip information as an optical signal.

An inspection method of a semiconductor integrated circuit according to the twenty-ninth aspect of the present invention is the method of the twentieth aspect, wherein the electromagnetic detection equipment is a magnetic field detection equipment used for reading of a semiconductor integrated circuit for outputting chip information as a magnetic line of force.

An inspection method of a semiconductor integrated circuit according to the thirtieth aspect of the present invention is the method of the twenty-first aspect, wherein the electromagnetic detection equipment is a magnetic field detection equipment used for reading of a semiconductor integrated circuit for outputting chip information as a magnetic line of force.

An inspection method of a semiconductor integrated circuit according to the thirty-first aspect of the present invention is the method of the twenty-second aspect, wherein the electromagnetic detection equipment is a magnetic field detection equipment used for reading of a semiconductor integrated circuit for outputting chip information as a magnetic line of force.

To be specific, each of the elements for outputting manufacturing information and inspection information as electromagnetic waves comprises a resistor for increasing heat generation, a diode for increasing light emission, and a wiring coil for increasing magnetic lines of force, so that any special processes are not necessary and chip information can be outputted, by an active signal provided in addition to a chip function, in a contactless manner from the semiconductor substrate without passing through an external port. Thus, it is possible to secure security in a state other than desired usage and obtain inspection information on a chip. Further, in an inactive state, the information can be made insignificant by turning on/off all the outputs of the elements, thereby enhancing security. Moreover, the fuse or the nonvolatile memory is arranged in series with the elements, so that a disconnection is made in a state other than desired usage. Thus, security can be further enhanced. Since the nonvolatile memory is rewritten, even when an inspection is necessary, the functions of elements can be reproduced again and thus security and ease of inspection can be achieved.

The semiconductor circuit is integrated with the light or magnetic field detection equipment and operated in synchronization with the ATE to obtain manufacturing information and inspection information on a chip, so that the semiconductor circuit can be used for an inspection sequence, trimming of a chip function, and repair of memory on the side of the ATE, thereby achieving an advantage of multifunction inspection with a small number of pins.

Light emission and magnetic lines of force are higher in detectivity and speed than heat generation and thus sufficiently usable in terms of inspection time.

The elements may be arranged in a redundant space except for a power supply and input/output pads. It is possible to effectively use the redundant space while minimizing the influence of the control circuit and the elements on a chip area. Any pattern image can be outputted for each designed product and any particular rules are not made. A barcode layout is made in a one-dimensional or two-dimensional manner, thereby achieving efficient detection. Further, continuous output based on an output intensity and clock synchronization is processed by the control circuit, thereby further increasing an amount of output data.

According to the present invention, the control circuit and elements for outputting chip information are provided without setting an extra external test terminal, the semiconductor integrated circuit for obtaining manufacturing information and inspection information in a contactless manner and the optical or magnetic field electromagnetic detection equipment are used in combination, and a system operating in synchronization with the ATE is constructed. Thus, it is possible to improve the quality of the semiconductor integrated circuit while achieving security for an actual product.

### BRIEF DESCRIPTION OF THE DRAWINGS

FIG. 1 is a structural diagram showing a semiconductor integrated circuit A comprising an element for outputting chip information as thermal energy according to (Embodiment 1) of the present invention;

FIG. 2 is a structural diagram showing a specific example of test information serving as chip information of (Embodiment 1);

FIGS. 3A and 3B are structural diagrams showing a heat detection equipment used in (Embodiment 1);

FIG. 4 is a structural diagram showing a semiconductor integrated circuit A comprising an element for outputting manufacturing information, which serves as chip information, as thermal energy according to (Embodiment 2) of the present invention;

FIG. 5 is a structural diagram showing a semiconductor integrated circuit A comprising an element for outputting chip information as thermal energy according to (Embodiment 3) of the present invention;

FIGS. 6A and 6B are structural diagrams showing a semiconductor integrated circuit A comprising an element for outputting chip information as thermal energy according to (Embodiment 4) of the present invention;

FIG. 7 is a structural diagram showing a semiconductor integrated circuit A comprising an element for outputting chip information as thermal energy according to (Embodiment 5) of the present invention;

FIG. 8 is a structural diagram showing a semiconductor integrated circuit A comprising an element for outputting chip information as thermal energy according to (Embodiment 6) of the present invention;

FIG. 9 is a structural diagram showing a semiconductor integrated circuit A comprising an element for outputting chip information as thermal energy according to (Embodiment 7) of the present invention;

FIG. 10 is a structural diagram showing a semiconductor integrated circuit A comprising an element for outputting chip information as thermal energy according to (Embodiment 8) of the present invention;

FIG. 11 is a structural diagram showing a semiconductor integrated circuit A comprising an element for outputting chip information as thermal energy according to (Embodiment 9) of the present invention;

FIG. 12 is a structural diagram showing a semiconductor integrated circuit A comprising an element for outputting chip information as thermal energy according to (Embodiment 10) of the present invention;

FIGS. 13A and 13B are structural diagrams showing a semiconductor integrated circuit A comprising an element for outputting chip information as thermal energy according to (Embodiment 11) of the present invention;

FIGS. 14A and 14B are structural diagrams showing a semiconductor integrated circuit A comprising an element for outputting chip information as thermal energy according to (Embodiment 12) of the present invention;

FIGS. 15A and 15B are explanatory drawings showing an inspection method of test information according to (Embodiment 13) of the present invention;

FIGS. 16A and 16B are flowcharts of (Embodiment 13);

FIGS. 17A and 17B are explanatory drawings showing an inspection method of manufacturing information according to (Embodiment 13) of the present invention;

FIGS. 18A, 18B, and 18C are flowcharts in which security is improved for a semiconductor integrated circuit A of (Embodiment 14) of the present invention;

FIG. 19 is a structural diagram showing a semiconductor integrated circuit B comprising an element for outputting chip information as optical energy according to (Embodiment 15) of the present invention;

FIG. 20 is a structural diagram showing an optical detection equipment used in (Embodiment 15);

FIG. 21 is a structural diagram showing a semiconductor integrated circuit C comprising an element for outputting chip information as magnetic energy according to (Embodiment 16) of the present invention; and

FIGS. 22A and 22B are structural diagrams showing a magnetic field detection equipment used in (Embodiment 16).

### DESCRIPTION OF THE EMBODIMENTS

The following will describe a semiconductor integrated circuit of the present invention in accordance with specific examples.

(Embodiment 1)

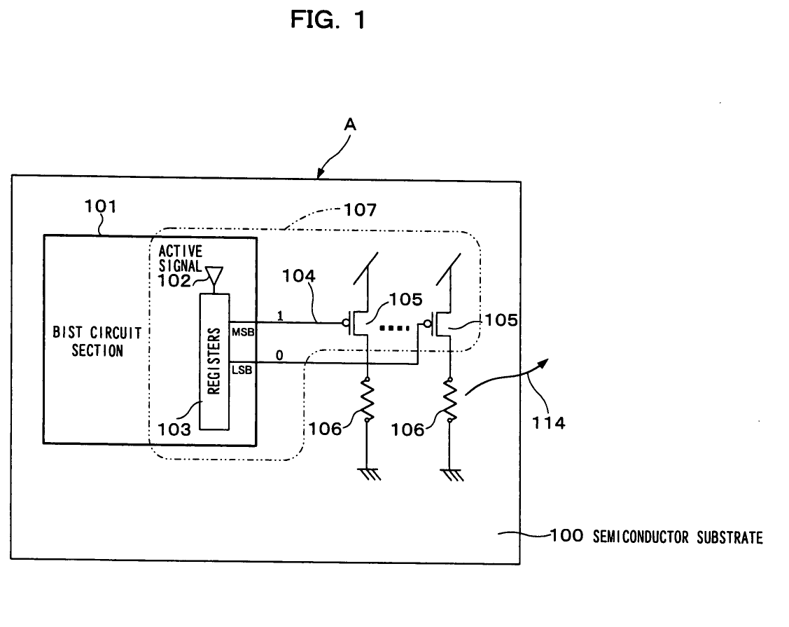

Referring to FIGS. 1 to 3A and 3B, the following will discuss a semiconductor integrated circuit A comprising an element for outputting chip information as thermal energy that is a kind of electromagnet waves, and a heat detection equipment as an electromagnetic detection equipment for reading.

As shown in FIG. 1, a BIST (Built In Self Test) circuit section 101 for self-examining whether the circuit section 101 can normally operate or not, elements 105, and resistors 106 for accelerating heat generation are configured on a semiconductor substrate 100 of the semiconductor integrated circuit A where a circuit for implementing desired functions is constructed. In this example, registers 103 and the elements 105 make up a control circuit 107 which is activated by a predetermined input signal on the semiconductor substrate. Further, in this example, semiconductor integrated circuit chip information is test information on self-examination results stored in the registers 103 of the BIST circuit section 101.

In an active state where an examiner qualified to read chip information sets an active signal 102 of the semiconductor integrated circuit at a predetermined reading permission state, chip information is read from an output 104 of the registers 103, to which the predetermined active signal 102 has been applied, and the chip information is outputted to the elements 105. Energization to the resistors 106 can be controlled by controlling the turning on/off of the elements 105 based on the chip information. On the other hand, in an inactive state where the active signal 102 is not set at the reading permission state, chip information is not read from the registers 103.

With this configuration, in the active state where the active signal 102 is set at the predetermined reading permission state, the resistors 106 are observed by a detection equipment capable of capturing heat generation (infrared light), so that test information serving as chip information can be read from the BIST circuit section 101 in a contactless manner without passing through an electrical path. An output circuit comprising the elements 105 and the resistors 106 has a simple configuration requiring a relatively small space, which enables effective use of a redundant space and thus offers an advantage to a layout.

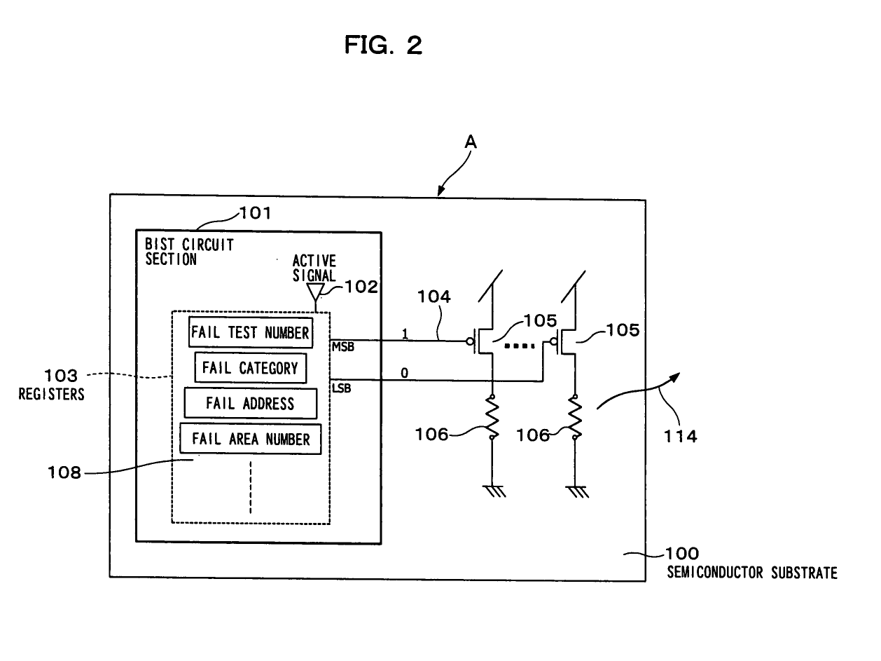

FIG. 2 shows a specific example of test information. Test information 108 including a fail test number, a fail category, a fail address, and a fail area is stored in the registers 103. The test information is obtained in a contactless manner without passing though an electrical path, which offers an advantage to an inspection. The advantage is not the location of an actual faulty part but the specified contents of a fault.

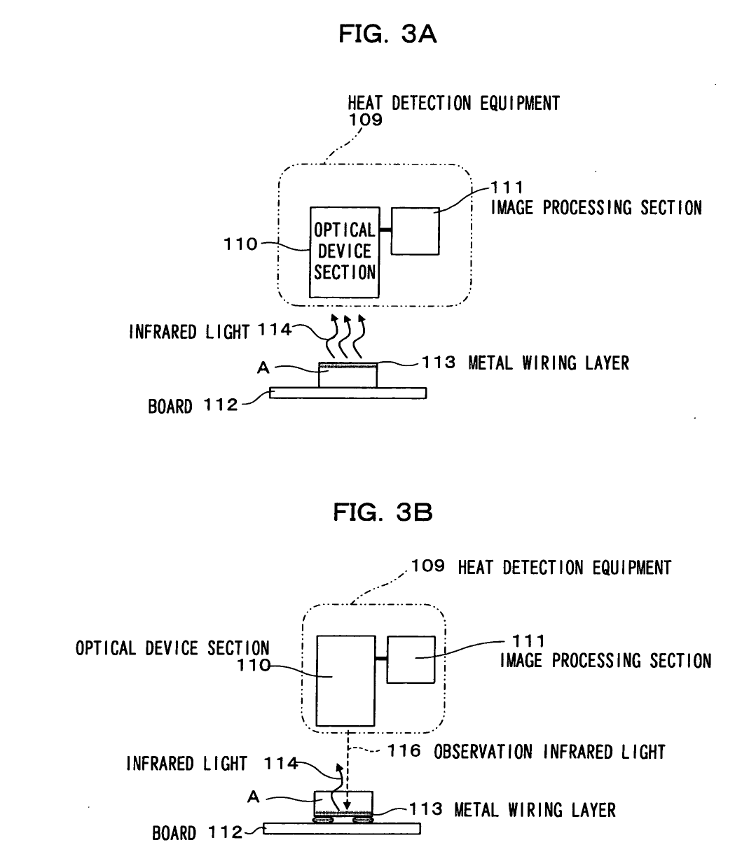

FIGS. 3A and 3B shows a heat detection equipment which can obtain test information in a contactless manner. A heat detection equipment 109 has an optical device section 110 as electromagnetic device section for capturing infrared light as an image and an image processing section 111 connected to the output of the optical device section 110.

The semiconductor integrated circuit A, with a metal wiring layer 113 located at the upper side thereof, is fixed on a board 112, and the light-receiving window of the optical device section 110 is directed to the top surface of the semiconductor integrated circuit A, so that infrared rays 114 generated by the heat generation of the resistors 106 according to chip information are captured as an image by the optical device section 110. This image can be inspected by the image processing section 111. The image processing section 111 can output the image to an external storage device or display device.

As shown in FIG. 3B, when the semiconductor integrated circuit A is flip-chip type which is mounted on the board 112 with the metal wiring layer 113 located at the lower side there of, observation infrared light 116 passing through a silicon substrate is emitted from the optical device section 110 to the semiconductor integrated circuit A, and reflected light of the semiconductor integrated circuit A is detected by the optical device section 110. At this point, the reflected light detected by the optical device section 110 is subjected to the interference of the infrared light 114 which has been generated by the heat generation of the resistors 106 according to chip information. Thus, the optical device section 110 can read the chip information and similarly capture an image to enable an inspection.

(Embodiment 2)

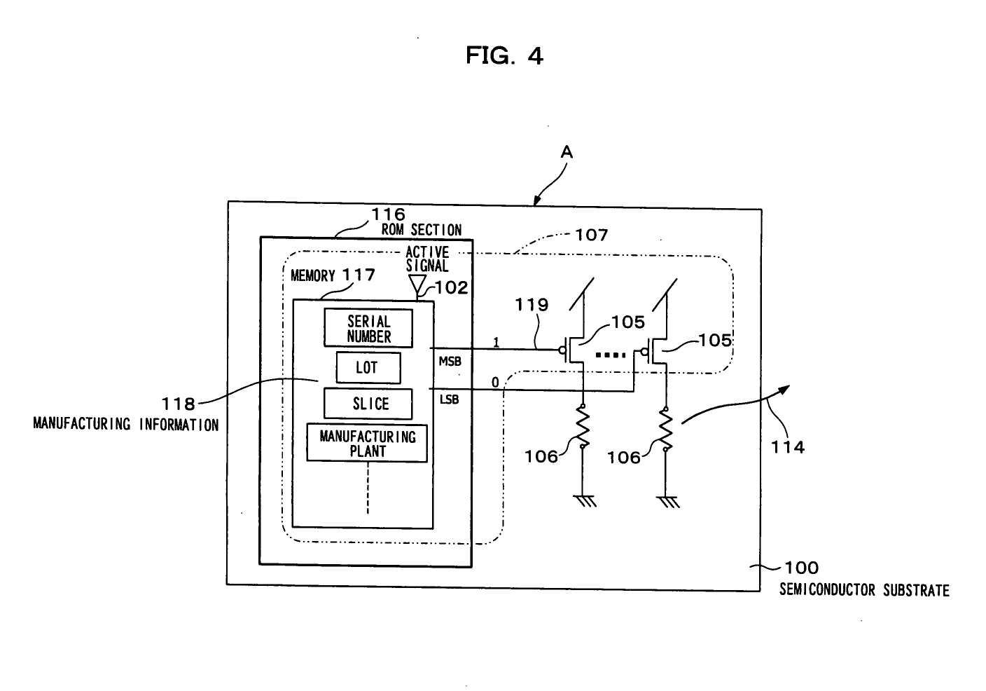

In (Embodiment 1), chip information is the test information of the BIST circuit section 101. As shown in FIG. 4, chip information maybe manufacturing information on a semiconductor integrated circuit.

In FIG. 4, a ROM section 116, elements 105, and resistors 106 for increasing heat generation are configured on a semiconductor substrate 100 of the semiconductor integrated circuit where a circuit for implementing desired functions is configured. Manufacturing information 118 including a serial number, a lot, a slice, and a manufacturing plant is stored in memory 117 of the ROM section 116. In this example, the ROM section 116 and the elements 105 make up a control circuit 107 which is activated by a predetermined input signal on the semiconductor substrate.

In an active state where an active signal 102 is set at a predetermined reading permission state, chip information is outputted from an output 119 of the memory 117 to the elements 105. Energization to the resistors 106 is controlled by controlling the turning on/off of the elements 105 based on the chip information.

With this configuration, the resistors 106 are observed by a heat detection equipment capable of capturing infrared light of heat generation, so that manufacturing information can be read in a contactless manner without passing through an electrical path. An output circuit comprising the elements 105 and the resistors 106 has a simple configuration requiring a relatively small space, which enables effective use of a redundant space and thus offers an advantage to a layout.

(Embodiment 3)

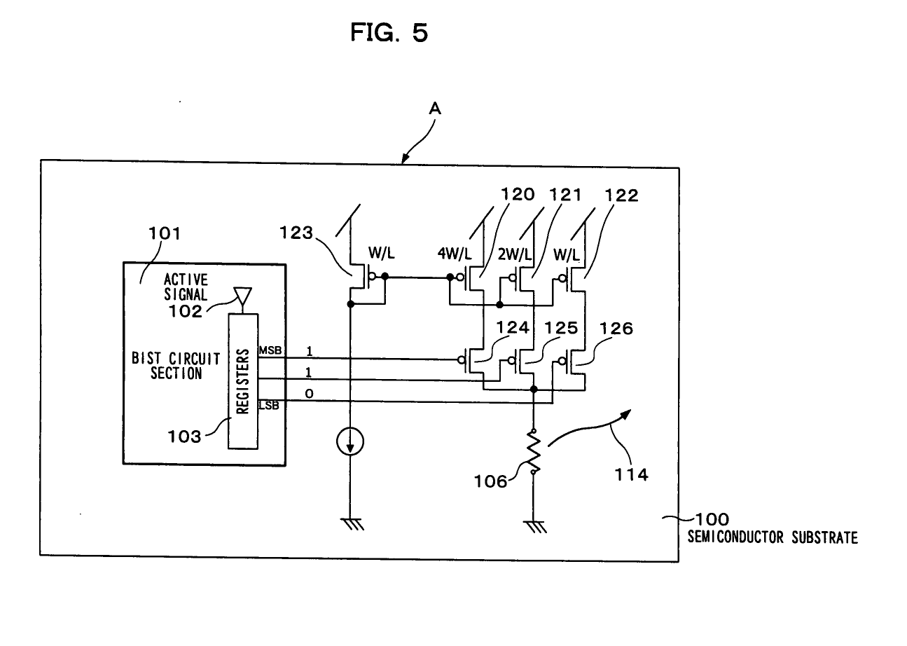

In the foregoing embodiments, the output levels of the elements 105 cannot be switched. Referring to FIG. 5, the following will discuss an example where an output level is variable in the semiconductor integrated circuit A of (Embodiment 1). Constituent elements having the same operations are indicated by the same reference numerals.

As shown in FIG. 5, selection transistors 120, 121, and 122 formed with different sizes (width: W/length: L), a current mirror circuit 123, elements 124, 125, and 126, and a resistor 106 for increasing heat generation are provided on a semiconductor substrate 100.

The size of the selection transistor 120 is 4W/L, the size of the selection transistor 121 is 2W/L, and the size of the selection transistor 122 is W/L. The element 124 is connected in series with the output of the selection transistor 120, the element 125 is connected in series with the output of the selection transistor 121, and the element 126 is connected in series with the output of the selection transistor 122. One ends of the elements 125 and 126 are connected to each other and grounded through the resistor 106.

The inputs of the elements 125 and 126 are switched by bit signals obtained by outputting chip information, which is obtained from a BIST circuit section 101 configured on the semiconductor substrate 100, to an output 104 of resistors 103 by a predetermined active signal 102.

With this configuration, power is supplied to the resistors 106 through one or more of the selection transistors 120 to 122 according to the output level of the output 104, and an amount of heat generated by the resistor 106 is changed with the output level of the output 104. In this case, constant current is secured by the current mirror 123, so that different amounts of heat can be liberated with stability.

Therefore, the light-receiving window of the optical device section of the heat detection equipment 109 is directed to the semiconductor integrated circuit A as shown in FIGS. 3A and 3B, so that the test results of the BIST circuit section 101 can be read from the outside in a contactless manner. It is possible to produce the effect of increasing an amount of information with the number of levels of brightness.

In this case, an amount of heat generated by the resistor 106 is changed according to test information. The present embodiment can be implemented also when chip information is manufacturing information including a serial number, a lot, a slice, and a manufacturing plant.

(Embodiment 4)

In (Embodiment 1) and (Embodiment 2), the resistor 106 is provided for each bit of chip information and chip information is outputted as thermal energy. In (Embodiment 3), the output levels of the elements 124 to 126 are switched and chip information of a plurality of bits is outputted by the single resistor 106. (Embodiment 4) is different from the foregoing embodiments only in that chip information is outputted as thermal energy a plurality of times for each bit in a time sharing manner.

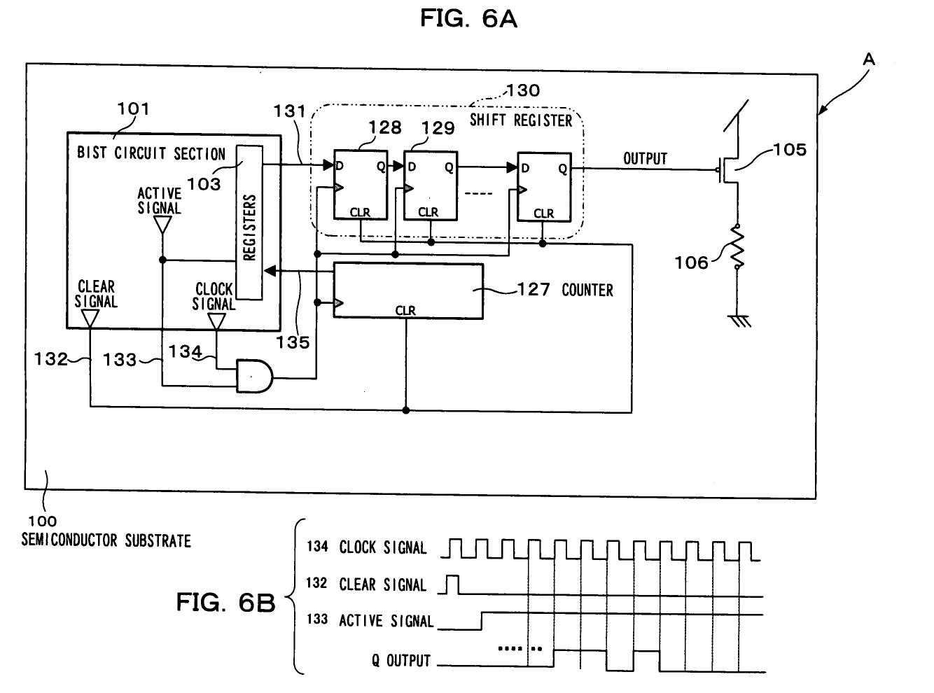

As shown in FIG. 6A, a counter 127, a shift register 130 comprising D flip-flops 128, 129, . . . connected in series, an element 105, and a resistor 106 for increasing heat generation are provided on a semiconductor substrate 100.

In an active state where an active signal 133 is set at a predetermined reading permission state, output bits are switched and outputted in bit serial form to an output 131 from registers 103 of a BIST circuit section 101 configured on the same semiconductor substrate 100, every time a switching instruction is issued by an output 135 of the counter 127.

As shown in FIG. 6B, when the active signal 133 is set at the active state after a clearing operation is performed on the counter 127 and the shift register 130 in response to a clear signal 132, output bits are switched and outputted, as described above, from the registers 103 to the shift register 130 based on the output 135 of the counter 127 in synchronization with a clock signal 134. Energization to the resistor 106 is controlled by turning on/off the element 105 based on chip information which has been outputted in bit serial form from the output of the shift register 130.

Therefore, the chip information is sequentially outputted to the output 131 in timing with the clock signal 134. The light-receiving window of the optical device section of the heat detection equipment 109 is directed to the semiconductor integrated circuit A as shown in FIGS. 3A and 3B, so that the test results of the BIST circuit section 101 can be read from the outside in a contactless manner. Further, it is possible to produce the effect of increasing an amount of information according to the time base.

In this case, an amount of heat generated by the resistor 106 is changed according to test information. The present embodiment can be implemented also when chip information is manufacturing information including a serial number, a lot, a slice, and a manufacturing plant.

(Embodiment 5)

In the foregoing embodiments, only chip information is outputted from the resistor 106. (Embodiment 5) is different only in that a given output state is outputted, for a bit with inactive chip information, from a resistor 106 to improve security.

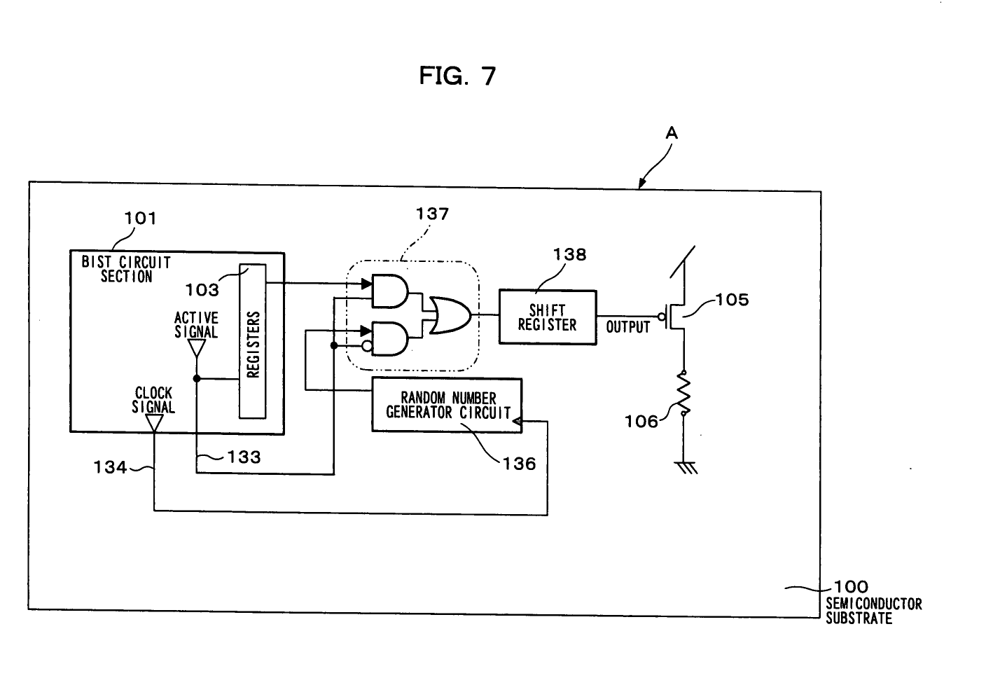

As shown in FIG. 7, a random number generator circuit 136, a multiplexer 137, a shift register 138, an element 105, a resistor 106 and so on are provided on a semiconductor substrate 100.

In an active state where an active signal 133 is set at a predetermined reading permission state, chip information obtained from a BIST circuit section 101 configured on the same semiconductor substrate 100 is read from registers 103 and outputted to the shift register 138 through the multiplexer 137 in synchronization with a clock signal 134. Energization to the resistor 106 is controlled by turning on/off the element 105. In FIG. 7, the counter 127 of FIGS. 6A and 6B is omitted.

On the other hand, when the active signal 133 is in an inactive state, the output of the random number generator circuit 136 is outputted to the shift register 138 through the multiplexer 137, so that insignificant chip information is outputted from the element 105 comprising a resistor for increasing heat generation and thus security can be improved.

To be specific, regardless of whether the active signal 133 is in an active state or an inactive state, some kind of changed information is outputted from the element 105. Thus, even if a person not qualified to read chip information performs reading with the heat detection equipment 109 shown in FIGS. 3A and 3B to illicitly search for the active state, it is not possible to distinguish between the active state and the inactive state of the active signal 133 only with the read contents of the heat detection equipment 109.

On the other hand, when an examiner is qualified to read chip information, the information is read with the heat detection equipment 109 in an active state where an active signal 102 of a semiconductor integrated circuit is set at the predetermined reading permission state. Alternatively, the active signal 102 is switched from an inactive state to an active state while the information is read with the heat detection equipment 109. Of the information read with the heat detection equipment 109, only reading results in a period when the active signal 102 is in the active state are used as valid chip information.

(Embodiment 6)

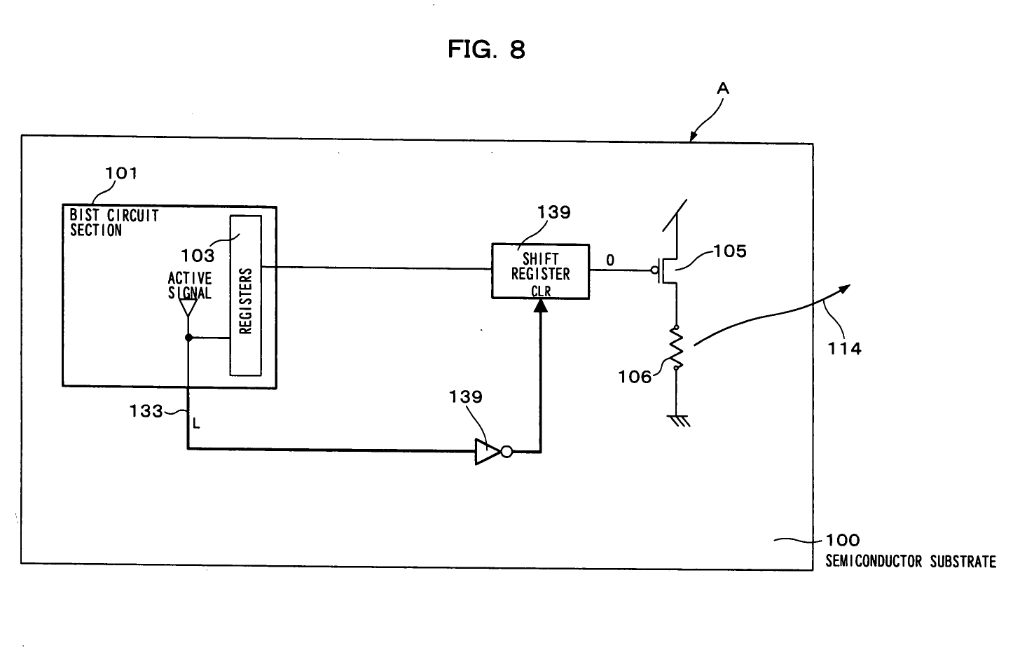

FIG. 8 shows (Embodiment 6).

In (Embodiment 5), when the active signal 102 is in an inactive state, energization to the resistor 106 is controlled by the output of the random number generator circuit 136 through the shift register 138 and the element 105 to disturb illicit reading, whereas in FIG. 8, an active signal 133 is connected to a clear terminal CLR of the shift register 138 through an inverter 139. Therefore, when the active signal 133 is set at an active state, chip information obtained from a BIST circuit section 101 is read from registers 103 and outputted to the shift register 138 in synchronization with a clock signal 134. Energization to a resistor 106 is controlled by turning on/off an element 105. In FIG. 8, the counter 127 of FIGS. 6A and 6B is omitted.

On the other hand, when the active signal 133 is in an inactive state, the shift register 138 is cleared through the inverter 139, “0” is repeatedly read from the output of the shift register 138, and the resistor 106 is continuously energized through the element 105. In other words, in a normal operation mode where the active signal 133 is in an inactive state, chip information is outputted as insignificant chip information from the resistor 106 for increasing heat generation and thus it is not possible to recognize whether a semiconductor integrated circuit has the function of reading chip information, so that security can be improved with simple control.

(Embodiment 7)

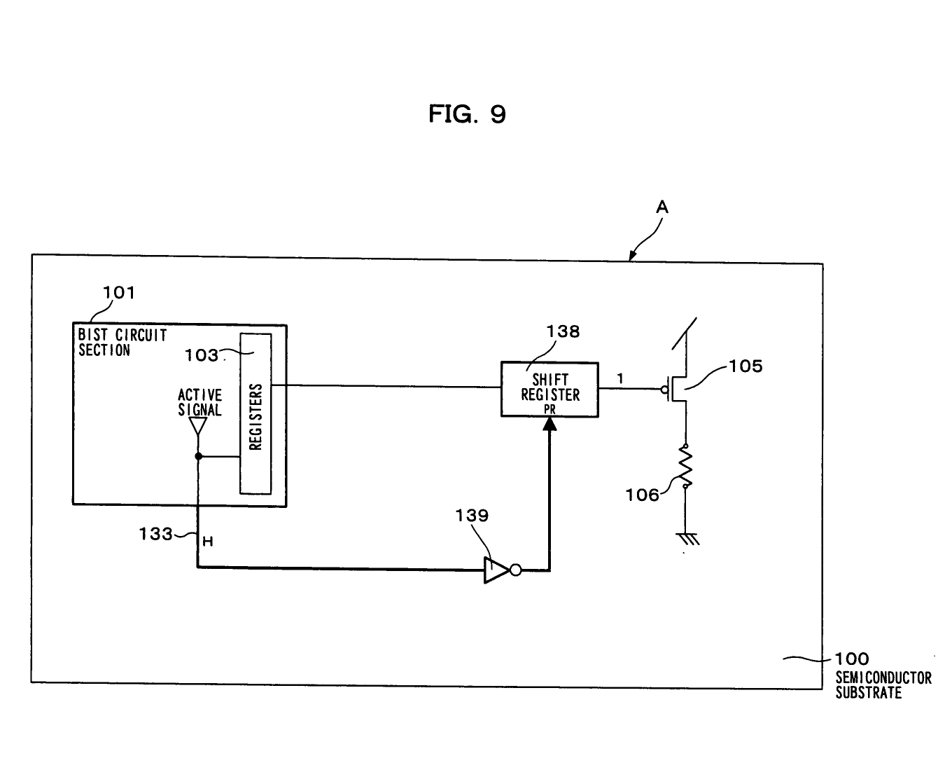

FIG. 9 shows (Embodiment 7).

In (Embodiment 6), when the active signal 133 is in an inactive state, the resistor 106 is continuously energized to improve security. FIG. 9 is different from FIG. 8 only in that an active signal 133 is connected to a preset terminal PR of the shift register 138 via an inverter 139.

Therefore, when the active signal 133 is set at an active state, chip information obtained from a BIST circuit section 101 is read from registers 103 and outputted to the shift register 138 in synchronization with a clock signal 134, and energization to a resistor 106 is controlled by turning on/off an element 105.

On the other hand, when the active signal 133 is in an inactive state, the shift register 138 is preset at “1” through the inverter 139, “1” is repeatedly read from the output of the shift register 138, and the resistor 106 is continuously turned off by repeatedly turning off an element 105.

In other words, in a normal operation mode where the active signal 133 is in an inactive state, it is not possible to recognize whether a semiconductor integrated circuit has the function of reading chip information, so that security can be improved with simple control. Further, it is possible to offer the advantage of reducing current consumption.

(Embodiment 8)

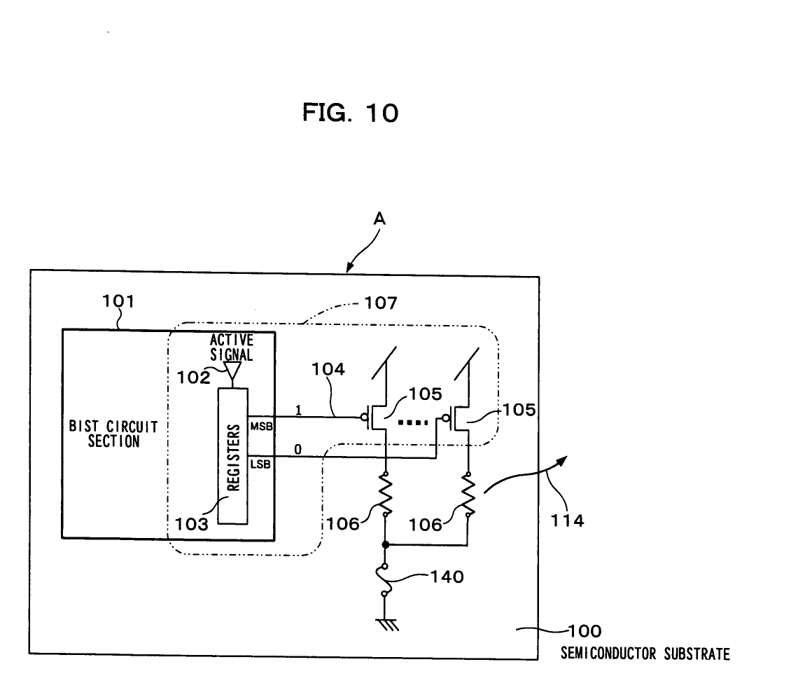

FIG. 10 shows another embodiment of FIG. 1.

In FIG. 1, one ends of the resistors 106 are directly grounded. In the example of FIG. 10, one ends of resistors 106 are connected to each other and grounded via a metal fuse 140.

In this configuration, the metal fuse 140 is disconnected by a laser trimmer or the like after chip information is obtained during an inspection, so that the function of the resistor 106 is suspended. Thus, security can be considerably improved.

The above explanation described an example of (Embodiment 1). The metal fuse 140 may be inserted in series with the resistor 106 in other embodiments.

(Embodiment 9)

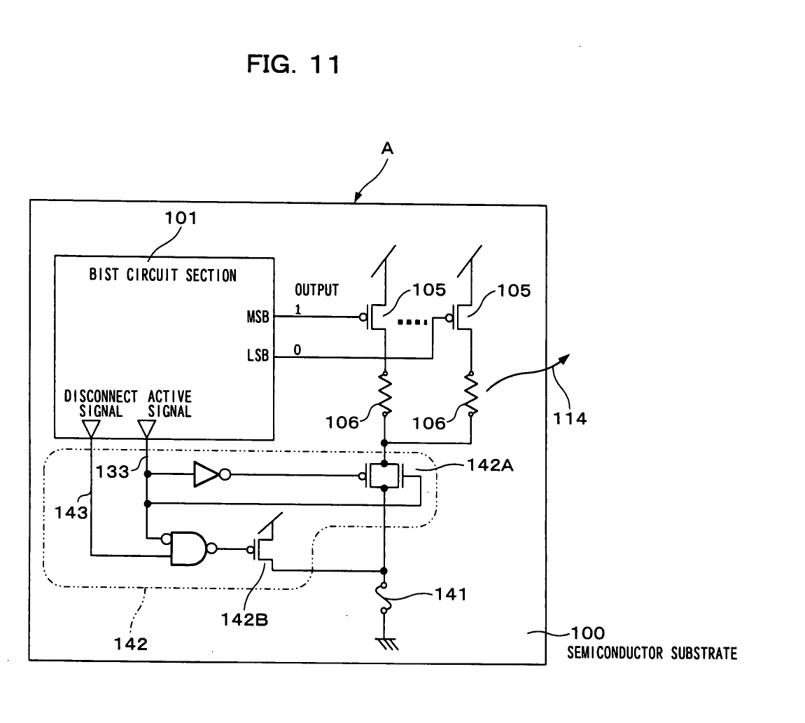

FIG. 11 shows another embodiment of FIG. 10.

In FIG. 10, the metal fuse 140 is directly inserted to one ends of the resistors 106. This embodiment is different only in that an electrical fuse 141 and a driver circuit section 142 for disconnection are provided. Reference numeral 143 denotes a disconnect signal.

Therefore, an active signal 133 is brought into an inactive state after chip information is obtained during an inspection (the active signal controls a transfer gate for interrupting the current paths of resistors 106 and is brought into an off state when power is turned off), the disconnect signal 143 is brought into an active state, and a current on the order of milliamperes is passed through the electrical fuse 141 by the driver circuit section 142 for disconnection, so that a high resistance state is generated and thus the functions of the resistors 106 can be suspended. Thus, it is possible to remarkably improve security without the need for a special device such as a laser trimmer.

The driver circuit section 142 for disconnection operates as below:

The active signal 133 has the function of controlling, at a transfer gate 142A, output to elements 105 and the energization and interruption of the resistors 106. Output is performed to the elements 105 in an active state and the transfer gate 142A is turned on, so that the current paths are secured and desired heat 114 is generated. In an inactive state, output to the elements 105 is prohibited and the transfer gate 142A is turned off, so that the current paths are interrupted.

When the active signal 133 is brought into an inactive state and the current paths of the resistors 106 are interrupted, the disconnect signal 143 is brought into an active state, so that an electrical fuse disconnection driver 142B with driving capability of the order of milliamperes is turned on. Thus, the electrical fuse 141 can be disconnected without being affected by the elements 105 or the resistors 106.

(Embodiment 10)

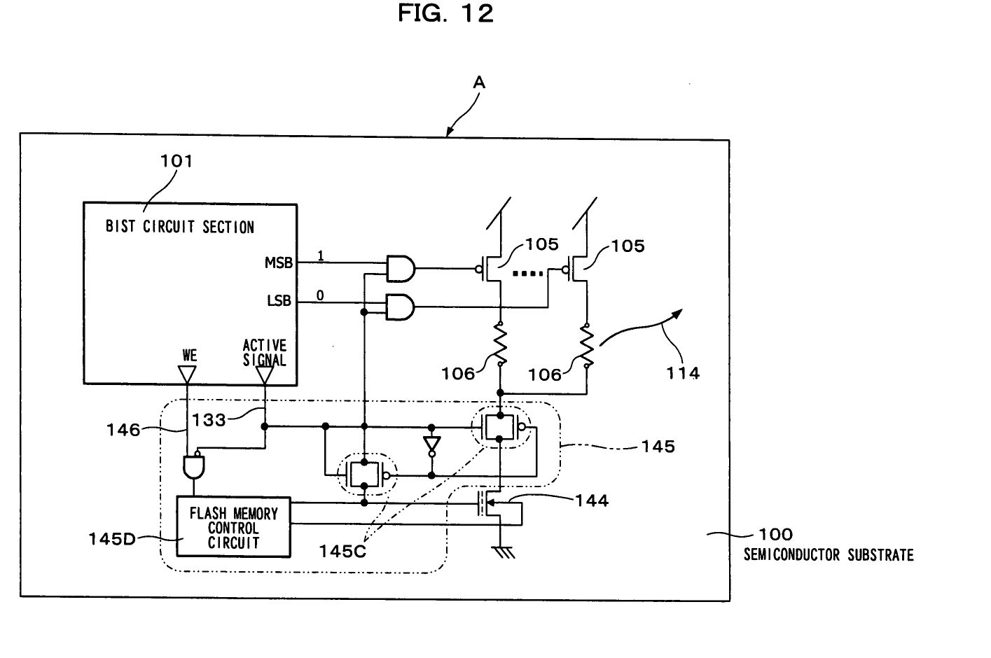

FIG. 12 shows another embodiment of FIG. 10.

In FIG. 10, the metal fuse 140 is directly inserted to one ends of the resistors 106. This embodiment is different only in that a flash memory 144 and a flash memory control circuit section 145 are provided. The flash memory 144 is connected in series with resistors 106. When chip information is obtained, the flash memory 144 is used in an on state in which the memory cell current of the flash memory 144 is applied.

After chip information is obtained, an active signal 133 is brought into an inactive state and a WE signal 146 is brought into an active state. Then, all the data of the flash memory 144 is rewritten to that of an off state, in which no memory cell current is applied, by the flash memory control circuit section 145 and the functions of the resistors 106 are suspended. When an inspection is necessary, the data is rewritten to that of an on state, in which memory cell current is applied, by using the advantage of the characteristics of the flash memory 144, so that it is possible to reproduce the functions of the resistors 106 and achieve the coexistence of security and ease of inspection. In the flash memory 144, an output circuit is turned on in an active state and turned off in an inactive state. The output circuit of the flash memory 144 is turned off all the time after the rewriting.

The flash memory control circuit section 145 operates as below:

The active signal 133 has the function of controlling, at transfer gates 145C, output to elements 105, the on state of the flash memory, and the energization and interruption of the resistors 106. Output to the elements 105 is performed in an active state, the transfer gates 145C are turned on, and the channel of the flash memory 144 is turned on, so that current paths are secured and desired heat 114 is generated. The flash memory 144 may be turned on when a normal power supply Vdd is applied to the gate of the flash memory 144. In an inactive state, output to the element 105 is prohibited, the transfer gates 145C are turned off, and the channel of the flash memory 144 is turned off, so that the current paths are interrupted.

The active signal 133 is brought into an inactive state and the current paths of the resistors 106 are interrupted. In this state, a rewriting permission signal 146 is brought into an active state, so that a high voltage required for rewriting data of the flash memory is generated from the flash memory control circuit 145D and the voltage is applied between the gate of the flash memory 144 and the substrate. Thus, the channel of the flash memory 144 can be always turned off without being affected by the elements 105 or the resistors 106.

(Embodiment 11)

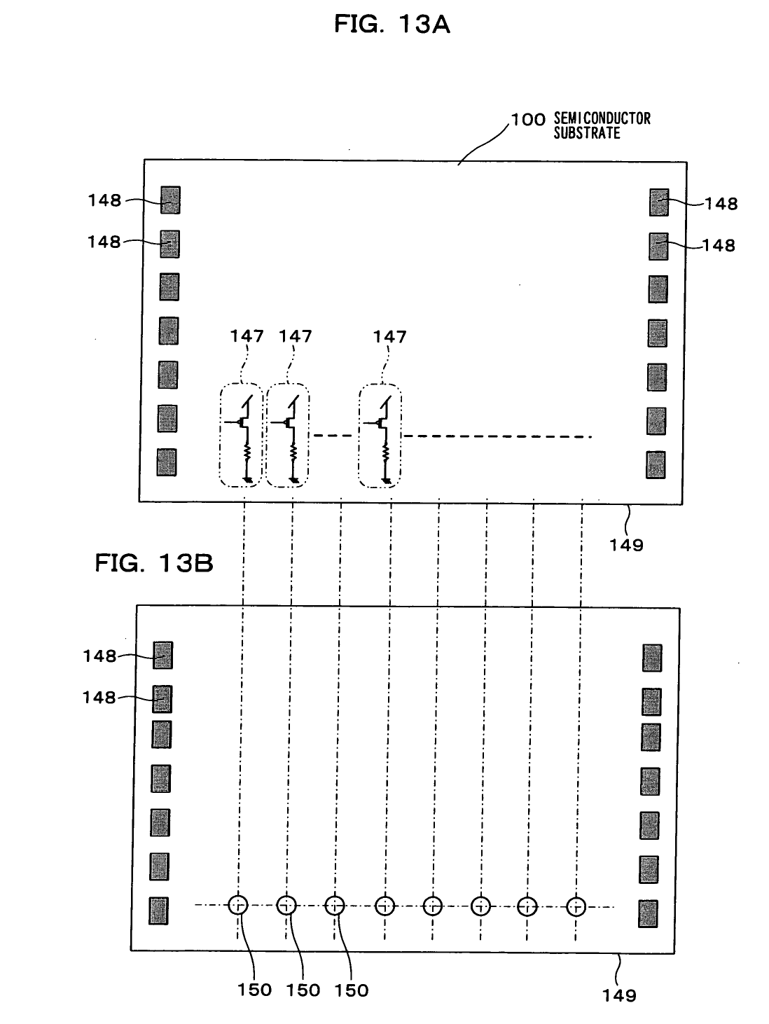

FIG. 13A shows a specific arrangement example of the elements 105 and the resistors 106 on the semiconductor substrate 100 according to the foregoing embodiments. As shown in FIG. 13A, units 147 comprising the elements 105 and the resistors 106 are arranged in series at established intervals and in a row in a given redundant space on the semiconductor substrate 100, except for pads 148 including input/output buffers and power supplies. In this arrangement, in order to limit a detection area during reading by the heat detection equipment 109, the units 147 are arranged close to a side 149 of the semiconductor substrate 100. The side 149 is disposed between the lines of the pads 148 disposed on the right and left ends of the semiconductor substrate 100.

With this arrangement, when chip information is read in response to the active signal 133 in an active state, infrared rays are generated, according to the chip information, from positions 150 of the resistors 106 of the units 147 near the side 149 of the semiconductor substrate 100, as indicated by virtual lines of FIG. 13B. Therefore, it is possible to read the chip information while directing the light-receiving window of an optical device section 110 of the heat detection unit 109 close to the side 149, and an image processing section 111 performs image processing on reading results with a bar code or the like. Thus, it is possible to specify and read chip information with a relatively simple arrangement, without the need for superimposing a CAD layout on an image.

(Embodiment 12)

In FIGS. 13A and 13B, the units 147 of the elements 105 and the resistors 106 are arranged in a one-dimensional manner. (Embodiment 12) describes another specific example in which units 147 are arranged in a two-dimensional arrangement.

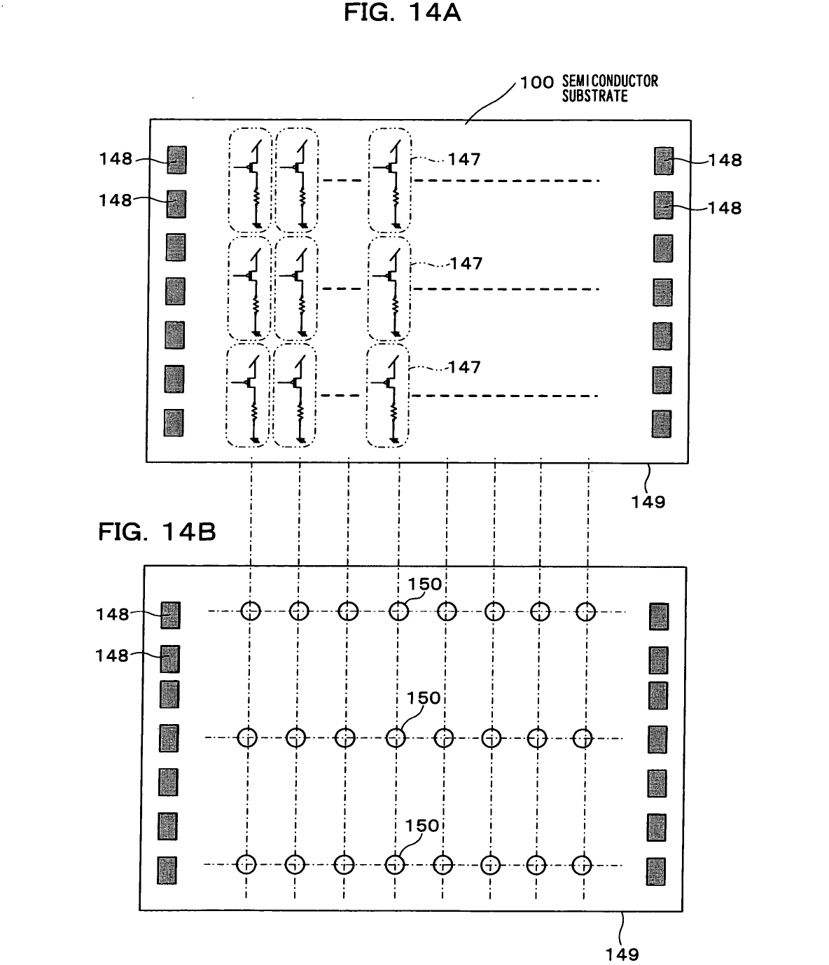

As shown in FIG. 14A, the units 147 comprising elements 105 and resistors 106 are arranged in series at established intervals and in a row in a given redundant space on the semiconductor substrate 100, except for pads 148 including input/output buffers and power supplies. The units 147 are arranged also in the vertical direction, which is the direction of the arrangement of the pads 148.

With this configuration, when chip information is read in response to the active signal 133 in an active state, infrared rays are generated according to the chip information from positions 150 of the resistors 106 of the units 147 as indicated by virtual lines of FIG. 14B. The light-receiving window of an optical device section 110 of the heat detection equipment 109 is directed to read the chip information, so that the chip information can be efficiently outputted as a two-dimensional bar code image. Further, an amount of chip information can be increased relative to that of the one-dimensional arrangement.

(Embodiment 13)

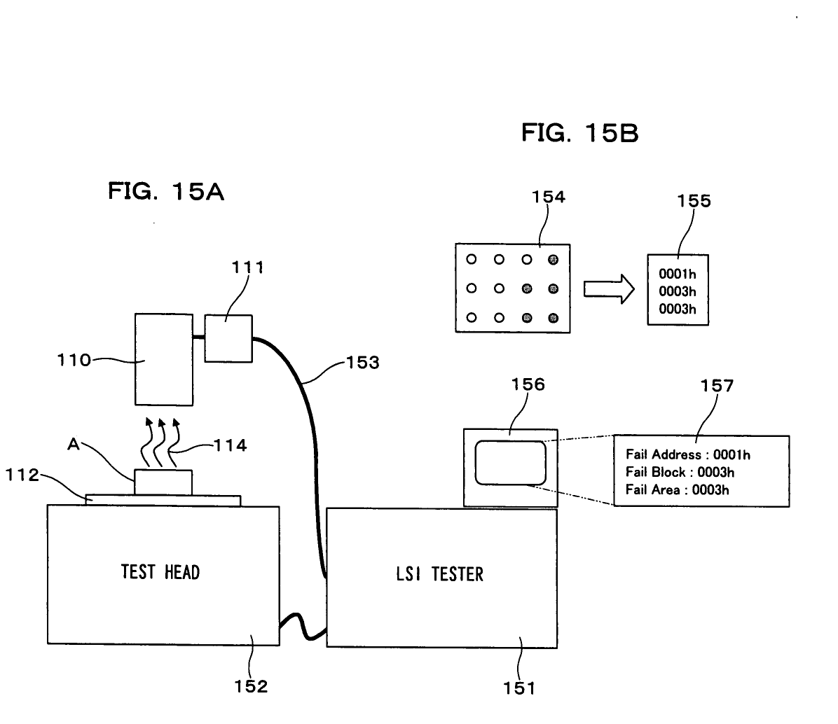

FIGS. 15A and 15B show a specific method of inspecting a semiconductor integrated circuit A which can output chip information as a two-dimensional bar code image as shown in FIGS. 14A and 14B.

As shown in FIG. 15A, a test signal is transmitted from an LSI tester as ATE (Automated Test Equipment) 151 to a test head 152, and an electric signal is received by a board 112 and applied to the semiconductor substrate 100 of the semiconductor integrated circuit A. In response to the test signal, the infrared light 114 generated by heat from the resistors 106 of the units 147 of the semiconductor integrated circuit A converts an image to significant inspection data 153 by means of the optical device section 110 and the image processing section 111. To be specific, as shown in FIG. 15B, code information 155 is outputted as the inspection data 153 according to the pattern of a two-dimensional bar code image 154 having been inputted to the image processing section 111 through the optical device section 110.

The inspection data 153 is read by the LSI tester 151 and stored as a test result corresponding to the test signal. Thereafter, specific contents 157 of the test result is displayed on a display 156 of the LSI tester 151. Thus, it is not necessary to obtain test results through the test head 152 of the LSI tester 151.

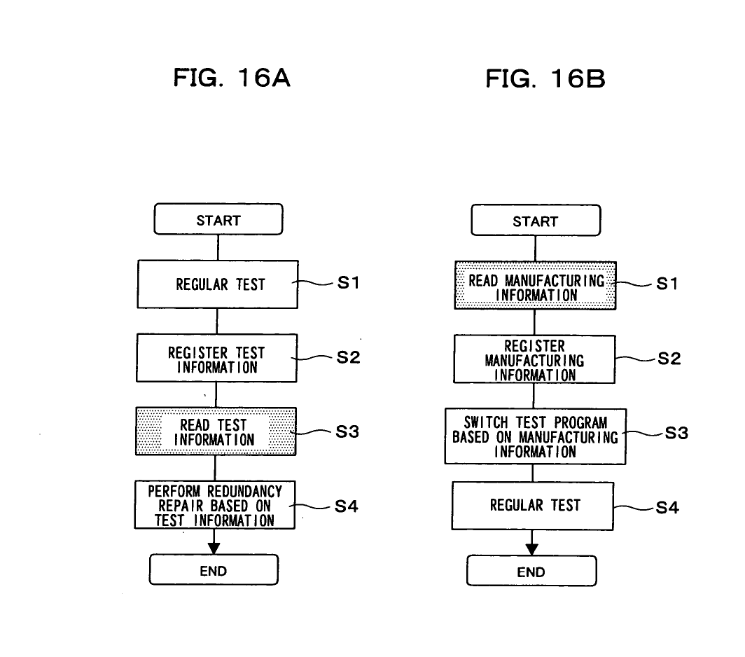

FIG. 16A shows a specific inspection flow of this case.

After an inspection is started, a regular test (S1) is conducted. For example, the fail address information of RAM is read and then registered in the storage medium of the LSI tester 151 (S2). Then, test information stored in the LSI tester 151 is read (S3), redundancy repair is performed by a fuse or nonvolatile memory (S4), and the inspection is completed. Thus, without obtaining chip information from the test head of the LSI tester, chip information can be retrieved in a contactless manner. A change of the sequence of a program, redundancy repair, and trimming can be performed in synchronization with the LSI tester during an inspection, thereby providing products with high quality and high yields.

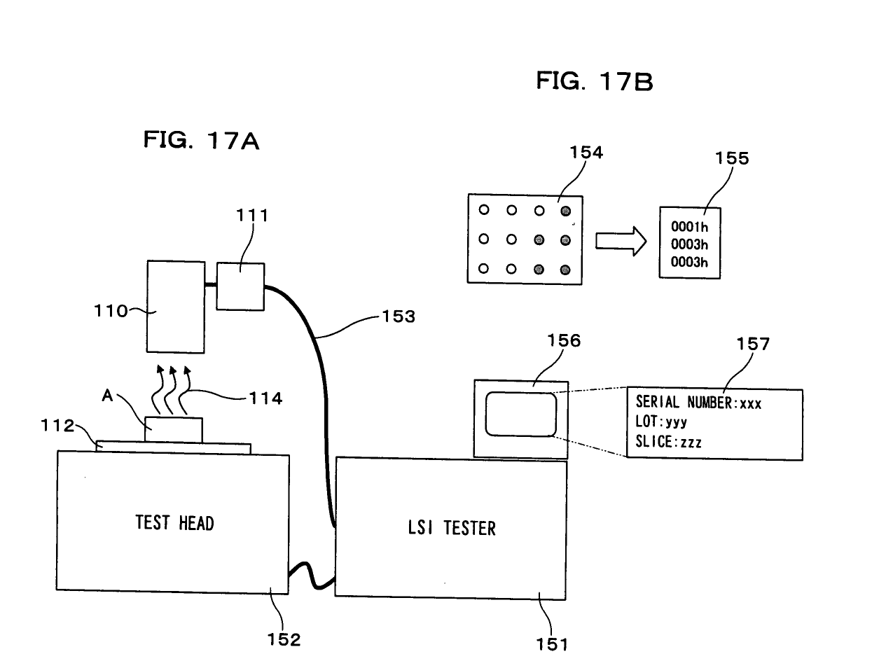

FIGS. 15A and 15B show the case where chip information is outputted as the infrared light 114 from the semiconductor integrated circuit A in response to the test signal and displayed with a fail address on the display 156. Similarly, the present embodiment can be implemented also when an instruction is issued to read manufacturing information of the chip information of the semiconductor integrated circuit A from the LSI tester 151 through the test head 152, and the manufacturing information is read through the infrared light 114 from the semiconductor integrated circuit A. FIGS. 17A and 17B show this case. Reading results including a serial number, a lot number, and a slice are displayed on the display 156 of the LSI tester 151. FIG. 16B shows the inspection flow of this case. In this inspection flow, after an inspection is started, manufacturing information is read (S1) and registered in the storage medium of the LSI TESTER 151 (S2). Then, the manufacturing information stored in the LSI TESTER 151 during the inspection is used as a flag, test program sequences are switched by software (S3), a regular test (S4) is conducted, and the inspection is completed. For example, a variety of programs and programs for RAM capacity can be switched with a single versatile inspection program based on manufacturing information. (Embodiment 13) described the semiconductor integrated circuit A which can output chip information as a two-dimensional bar code image. (Embodiment 13) can be similarly implemented when the semiconductor integrated circuit A can output chip information as a one-dimensional bar code image as shown in FIGS. 13A and 13B.

(Embodiment 14)

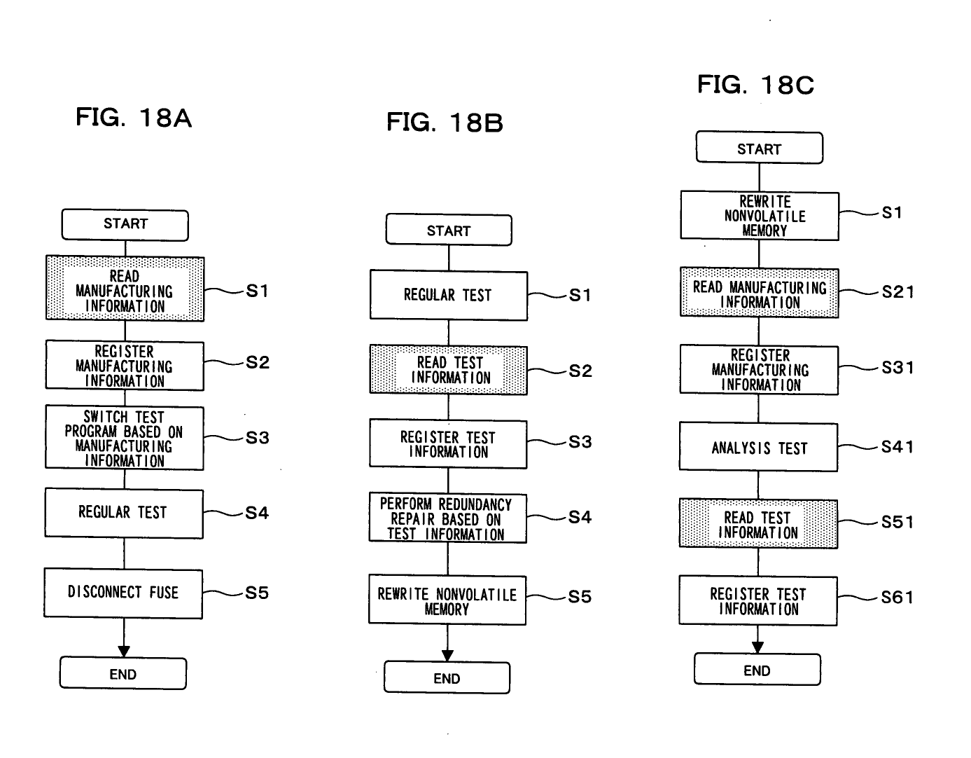

FIG. 18A shows a specific flow of an inspection which is performed for security on the semiconductor integrated circuit A having the metal fuse 140 or the electrical fuse 141 as shown in FIG. 10, 11 or 12, with the LSI TESTER 151. In this case, after an inspection is started, manufacturing information is read (S1) and registered in the storage medium of the LSI TESTER (S2) . Then, the manufacturing information stored in the LSI TESTER 151 during the inspection is used as a flag, test program sequences are switched by software (S3), and a regular test (S4) is performed. Thereafter, the fuse is disconnected (S5) and the inspection is completed. Since the function of the element for outputting the manufacturing information is suspended, the manufacturing information cannot be read again.

FIG. 18B shows a specific flow of an inspection performed for security on the semiconductor integrated circuit A having the flash memory 144 and the flash memory control circuit section 145 as shown in FIG. 12, with the LSI TESTER 151. In this case, after an inspection is started, a regular test is conducted (S1). For example, the fail address information of RAM is read (S2) and registered in the storage medium of the LSI TESTER 151 (S3). Then, based on test information stored in the LSI TESTER 151, redundancy repair is performed by the flash memory 144 which is nonvolatile memory (S4). Thereafter, the data of the nonvolatile memory is rewritten to a state in which no memory cell current is applied (S5), a disconnection is made, and the inspection is completed. Since the function of the element outputting test information is suspended, the test information cannot be read again.

FIG. 18C shows a specific flow in which chip information can be outputted again. In this case, after an inspection is started, the data of the nonvolatile memory provided for suspending the function of the element for outputting chip information is rewritten to enable the function of the element again (S1), and then manufacturing information is read (S2) and registered (S3). An analysis test is conducted (S4), test information obtained by the analysis test is read (S5) and registered (S6), and the analysis test is completed. Thus, even when an analysis is required after shipment, chip information can be outputted again, achieving a simple inspection.

(Embodiment 15)

The foregoing embodiments described the semiconductor integrated circuit A comprising the element for outputting chip information as heat. The same effect can be expected from a semiconductor integrated circuit B in which the element for outputting chip information as heat is replaced with an element for outputting chip information as an optical signal that is a kind of electromagnetic waves.

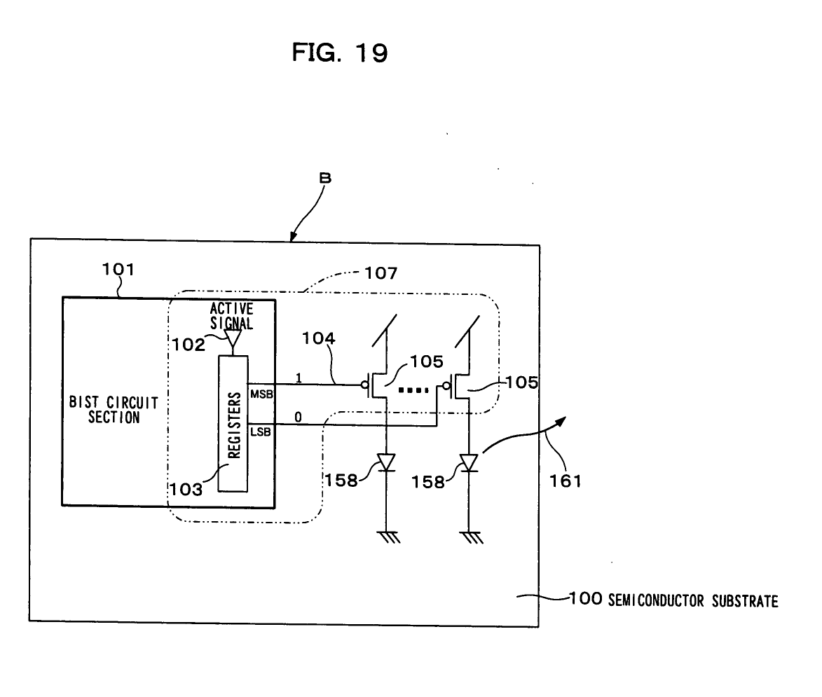

As shown in FIG. 19, a BIST circuit section 101 for self-examining whether the circuit section 101 can normally operate, elements 105, and diodes 158 for increasing light emission are configured on a semiconductor substrate 100 of the semiconductor integrated circuit where a circuit for implementing desired functions is constructed. In this example, registers 103 and the elements 105 make up a control circuit 107 which is activated by a predetermined input signal on the semiconductor substrate. Further, in this example, semiconductor integrated circuit chip information is test information or manufacturing information on self-examination results stored in the registers 103 of the BIST circuit section 101.

In an active state where an examiner qualified to read chip information or manufacturing information sets an active signal 102 of the semiconductor integrated circuit at a predetermined reading permission state, chip information is read from an output 104 of the registers 103, to which the predetermined active signal 102 has been applied, and outputted to the elements 105. Energization to the diodes 158 is controlled by controlling the turning on/off of the elements 105 based on the chip information. On the other hand, in an inactive state where the active signal 102 is not set at the reading permission state, chip information is not read from the registers 103.

With this configuration, in the active state where the active signal 102 is set at the predetermined reading permission state, the diodes 158 are observed by a detection equipment capable of capturing light emission, so that test information serving as chip information can be read from the BIST circuit section 101 in a contactless manner without passing through an electrical path. An output circuit comprising the elements 105 and the diodes 158 has a simple configuration requiring a relatively small space, which enables effective use of a redundant space and thus offers an advantage to a layout. Further, the information can be outputted faster than the chip information outputted through the thermal energy of the resistors 106.

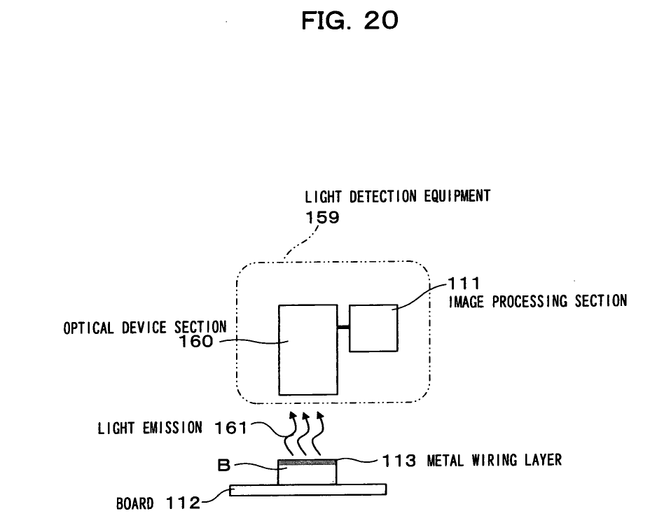

FIG. 20 shows a light detection equipment as an electromagnetic detection equipment, which can obtain test information in a contactless manner.

A light detection equipment 159 has an optical device section 160 for capturing light emission of the diodes 158 as an image and an image processing section 111 connected to the output of the optical device section 160.

The semiconductor integrated circuit B, with a metal wiring layer 113 located at the upper side thereof, is fixed on a board 112, and the light-receiving window of the optical device section 160 as an electromagnetic device section is directed to the top surface of the semiconductor integrated circuit A, so that light emission 161 of the diodes 158 based on chip information is captured as an image by the optical device section 160. This image is inspected by the image processing section 111. The image processing section 111 can output the image to an external storage device or display device.

FIGS. 19 and 20 show different points from FIGS. 1, 3A, and 3B. The configurations of FIGS. 4 to 18A, 18B, and 18C can be similarly implemented only by replacing the resistors 106 with the diodes 158.

(Embodiment 16)

FIGS. 1 to 18A, 18B, and 18C illustrate the semiconductor integrated circuit A comprising the element for outputting chip information as heat. The same effect can be expected from a semiconductor integrated circuit C in which the element for outputting chip information as heat is replaced with an element for outputting chip information as magnetic line of force that is a kind of electromagnetic waves.

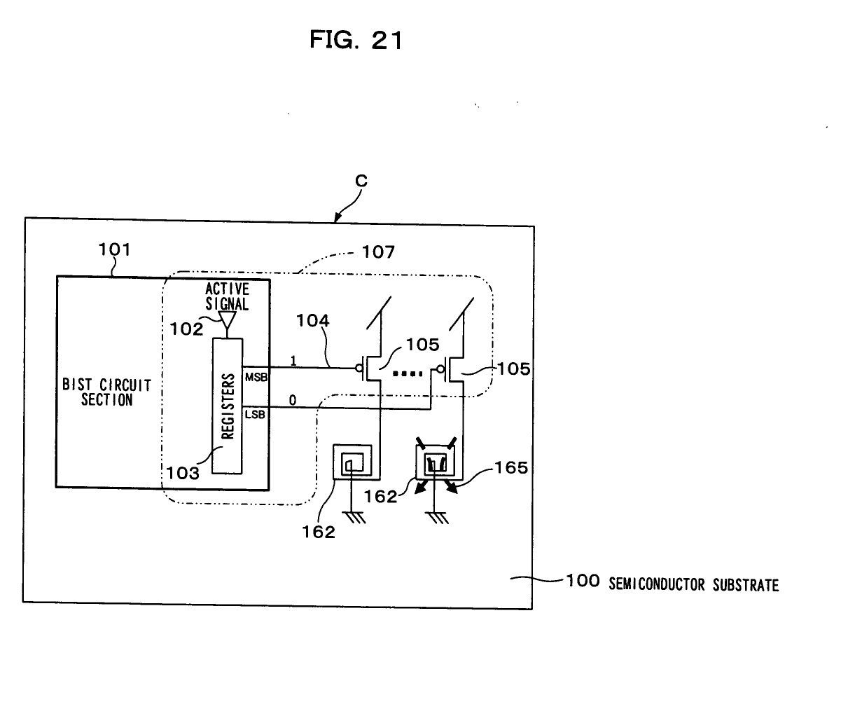

As shown in FIG. 21, a BIST circuit section 101 for self-examining whether the circuit section 101 can normally operate, elements 105, and wire coils 162 for increasing magnetic lines of force are configured on a semiconductor substrate 100 of the semiconductor integrated circuit where a circuit for implementing desired functions is constructed. In this example, registers 103 and the elements 105 make up a control circuit 107 which is activated by a predetermined input signal on the semiconductor substrate. Further, in this example, semiconductor integrated circuit chip information is test information or manufacturing information on self-examination results stored in the registers 103 of the BIST circuit section 101.

In an active state where an examiner qualified to read chip information or manufacturing information sets an active signal 102 of the semiconductor integrated circuit at a predetermined reading permission state, chip information is read from an output 104 of the registers 103, to which the predetermined active signal 102 has been applied, and outputted to the elements 105. Energization to the wire coils 162 is controlled by controlling the turning on/off of the elements 105 based on the chip information. On the other hand, in an inactive state where the active signal 102 is not set at the reading permission state, chip information is not read from the registers 103.

With this configuration, in the active state where the active signal 102 is set at the predetermined reading permission state, the wire coils 162 are observed by a detection equipment capable of capturing magnetic lines of force, so that test information serving as chip information can be read from the BIST circuit section 101 in a contactless manner without passing through an electrical path.

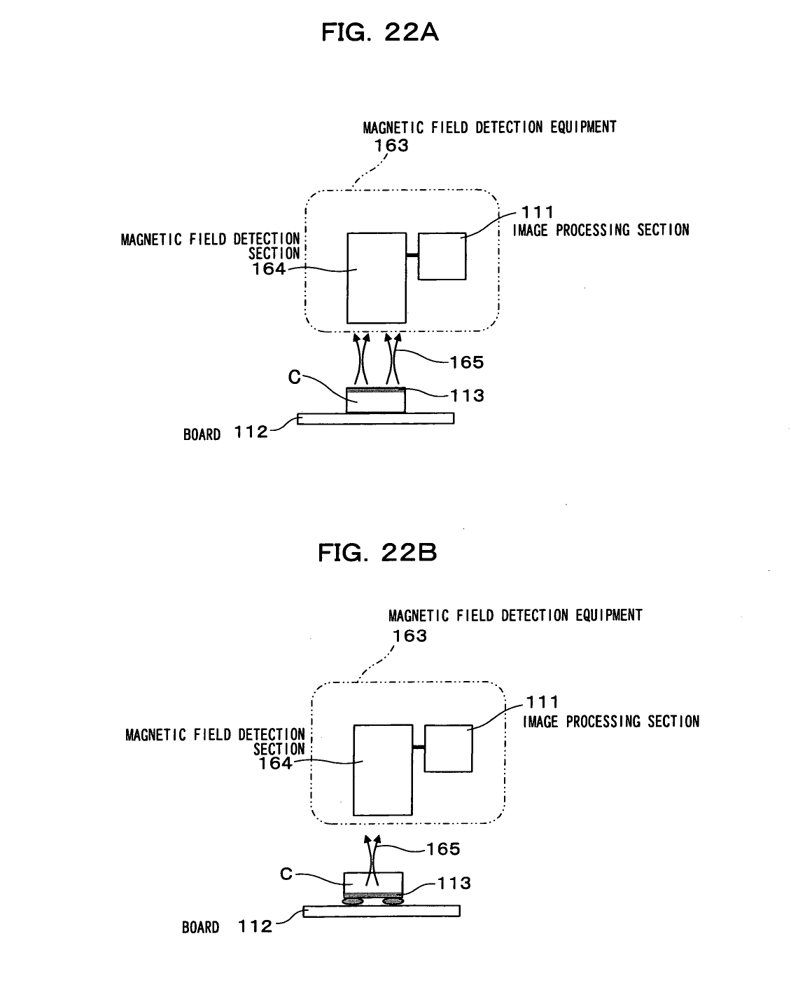

FIG. 22A shows a magnetic field detection equipment as an electromagnetic detection equipment, which can obtain test information in a contactless manner.

A magnetic field detection equipment 163 has a magnetic field detection device section 164 as an electromagnetic device section which captures the distribution of magnetic lines of force of the wire coil's 162 as an image and an image processing section 111 which is connected to the output of the magnetic field detection device section 164.

The semiconductor integrated circuit C, with a metal wiring layer 113 located at the upper side thereof, is fixed on a board 112, and the detection window of the magnetic field detection device section 164 is directed to the top surface of the semiconductor integrated circuit C, so that magnetic fluxes 165 of the wire coils 162 based on chip information are captured by the optical device section 160 as a distribution image of magnetic lines of force. This image is inspected by the image processing section 111. The image processing section 111 can output the image to an external storage device or display device.

In the case where chip information is read through thermal energy and optical energy as described above, when the semiconductor integrated circuit is mounted by flip-chip packaging, chip information is partially interrupted by the metal wiring layer 113 and thus becomes hard to obtain. In the case of the semiconductor integrated circuit C comprising the wire coils 162, as shown in FIG. 22B, even when the semiconductor integrated circuit C is mounted on the board 112 with the metal wiring layer 113 located at the lower side thereof, magnetic lines of force obtained after passing through the meal wiring layer 113 are captured by the magnetic field detection device section 164, so that the semiconductor integrated circuit of flip-chip type can be readily inspected in an extremely short time.

FIGS. 21, 22A, and 22B show different points from FIGS. 1, 3A, and 3B. The configurations of FIGS. 4 to 18A, 18B, and 18C can be similarly implemented only by replacing the resistors 106 with the wire coils 162 for increasing magnetic lines of force.

The semiconductor integrated circuit and the inspection method of the present invention are also applicable to a contactless IC card and a product field of a multilayer SiP and flip chip, in which manufacturing information (chip ID) or inspection information is hard to physically obtain. In the future, this technique is sufficiently applicable for the traceability of semiconductors improved in the field of on board equipments.

What is claimed is:

1. A semiconductor integrated circuit, comprising:
a semiconductor substrate,
a control circuit mounted on said semiconductor substrate and activated by a predetermined input signal, and
elements mounted on said semiconductor substrate and outputting chip information as electromagnetic waves in response to an output of the control circuit.

2. The semiconductor integrated circuit according to claim 1, wherein the chip information is manufacturing information or test information.

3. The semiconductor integrated circuit according to claim 1, wherein the elements are arranged in a one-dimensional manner or two-dimensional manner.

4. The semiconductor integrated circuit according to claim 1, wherein each element has a variable output.

5. The semiconductor integrated circuit according to claim 1, wherein the electromagnetic waves are outputted a plurality of times by activating the control circuit.

6. The semiconductor integrated circuit according to claim 1, wherein when the control circuit is in an inactive state, the elements are in a given output state.

7. The semiconductor integrated circuit according to claim 1, wherein when the control circuit is in an inactive state, the elements are in a given output state, and all the elements are selected and the electromagnetic waves are outputted in the given output state.

8. The semiconductor integrated circuit according to claim 1, wherein when the control circuit is in an inactive state, the elements are in a given output state, and all the elements are selected but no electromagnetic waves are outputted in the given output state.

9. The semiconductor integrated circuit according to claim 1, further comprising a fuse connected in series with the elements, the fuse being disconnected after the chip information is outputted.

10. The semiconductor integrated circuit according to claim 1, further comprising nonvolatile memory connected in series with the elements, the nonvolatile memory having data brought into a non-output state after the chip information is outputted.

11. An electromagnetic detection equipment used for reading of a semiconductor integrated circuit for outputting chip information as electromagnetic waves, comprising:
an electromagnetic device section for capturing electromagnetic waves from the semiconductor integrated circuit, and
a processing section for performing data conversion on information having been detected by the electromagnetic device section and obtaining chip information.

12. The electromagnetic detection equipment according to 11, further comprising an optical device section for capturing thermal energy from the semiconductor integrated circuit as infrared light, and a processing section for performing data conversion on information having been detected by the optical device section and obtaining chip information.

13. The electromagnetic detection equipment according to 11, further comprising an optical device section for capturing light emission from the semiconductor integrated circuit, and a processing section for performing data conversion on information having been received in the optical device section and obtaining chip information.

14. The electromagnetic detection equipment according to 11, further comprising a magnetic field detection device section for capturing a magnetic line of force from the semiconductor integrated circuit, and a processing section for performing data conversion on information having been detected in the magnetic field detection device section and obtaining chip information.

15. An inspection method of a semiconductor integrated circuit, the method comprising:
operating the electromagnetic detection equipment according to claim 11 and an automated test equipment simultaneously, and
analyzing, by means of the automated test equipment, chip information having been read by the electromagnetic detection equipment.

16. The inspection method of a semiconductor integrated circuit according to claim 15, further comprising controlling a processing flow based on the chip information.

17. The inspection method of a semiconductor integrated circuit according to claim 15, wherein the electromagnetic detection equipment is a heat detection equipment for reading of a semiconductor integrated circuit for outputting chip information as thermal energy, and the method further comprises operating the heat detection equipment and the automated test equipment simultaneously, and analyzing, by means of the automated test equipment, chip information having been read by the heat detection equipment.

18. The inspection method of a semiconductor integrated circuit according to claim 15, wherein the electromagnetic detection equipment is a light detection equipment for reading of a semiconductor integrated circuit for outputting chip information as an optical signal, and the method further comprises operating the light detection equipment and the automated test equipment simultaneously, and analyzing, by means of the automated test equipment, chip information having been read by the light detection equipment.

19. The inspection method of a semiconductor integrated circuit according to claim 15, wherein the electromagnetic detection equipment is a magnetic field detection equipment for reading of a semiconductor integrated circuit for outputting chip information as a magnetic line of force, and the method further comprises operating the magnetic field detection equipment and the automated test equipment simultaneously, and analyzing, by means of the automated test equipment, chip information having been read by the magnetic field detection equipment.

20. An inspection method of as a semiconductor integrated circuit for inspecting a semiconductor integrated circuit including a semiconductor substrate mounted with a control circuit activated by a predetermined input signal, elements for outputting chip information as electromagnetic waves in response to an output of the control circuit, and a fuse connected in series with the elements, the method comprising:
simultaneously operating an automated test equipment and an electromagnetic detection equipment including an electromagnetic device section for capturing magnetic waves from the semiconductor integrated circuit, and a processing section for performing data conversion on information having been detected in the electromagnetic device section and obtaining chip information, and
disconnecting the fuse in an inspection process before shipment.

21. An inspection method of a semiconductor integrated circuit for inspecting a semiconductor integrated circuit including a semiconductor substrate mounted with a control circuit activated by a predetermined input signal, elements for outputting chip information as electromagnetic waves in response to an output of the control circuit, and a nonvolatile memory connected in series with the elements, the method comprising:
simultaneously operating an automated test equipment and an electromagnetic detection equipment including an electromagnetic device section for capturing magnetic waves from the semiconductor integrated circuit, and a processing section for performing data conversion on information having been detected in the electromagnetic device section and obtaining chip information, and
bringing data of the nonvolatile memory having data into a non-output state in an inspection process before shipment.

22. An inspection method of a semiconductor integrated circuit for inspecting a semiconductor integrated circuit including a semiconductor substrate mounted with a control circuit activated by a predetermined input signal, elements for outputting chip information as electromagnetic waves in response to an output of the control circuit, and a nonvolatile memory connected in series with the elements, the method comprising:
simultaneously operating an automated test equipment and an electromagnetic detection equipment including an electromagnetic device section for capturing magnetic waves from the semiconductor integrated circuit, and a processing section for performing data conversion on information having been detected in the electromagnetic device section and obtaining chip information,
bringing data of the nonvolatile memory having data into a non-output state in an inspection process before shipment, and
rewriting the nonvolatile memory into a connecting state again to output the chip information again.

23. The inspection method of a semiconductor integrated circuit according to claim 20, wherein the electromagnetic detection equipment is a heat detection equipment used for reading of a semiconductor integrated circuit for outputting chip information as thermal energy.

24. The inspection method of a semiconductor integrated circuit according to claim 21, wherein the electromagnetic detection equipment is a heat detection equipment used for reading of a semiconductor integrated circuit for outputting chip information as thermal energy.

25. The inspection method of a semiconductor integrated circuit according to claim 22, wherein the electromagnetic detection equipment is a heat detection equipment used for reading of a semiconductor integrated circuit for outputting chip information as thermal energy.

26. The inspection method of a semiconductor integrated circuit according to claim 20, wherein the electromagnetic detection equipment is a light detection equipment used for reading of a semiconductor integrated circuit for outputting chip information as an optical signal.

27. The inspection method of a semiconductor integrated circuit according to claim 21, wherein the electromagnetic detection equipment is a light detection equipment used for reading of a semiconductor integrated circuit for outputting chip information as an optical signal.

28. The inspection method of a semiconductor integrated circuit according to claim 22, wherein the electromagnetic detection equipment is a light detection equipment used for reading of a semiconductor integrated circuit for outputting chip information as an optical signal.

29. The inspection method of a semiconductor integrated circuit according to claim 20, wherein the electromagnetic detection equipment is a magnetic field detection equipment used for reading of a semiconductor integrated circuit for outputting chip information as a magnetic line of force.

30. The inspection method of a semiconductor integrated circuit according to claim 21, wherein the electromagnetic detection equipment is a magnetic field detection equipment used for reading of a semiconductor integrated circuit for outputting chip information as a magnetic line of force.

31. The inspection method of a semiconductor integrated circuit according to claim 22, wherein the electromagnetic detection equipment is a magnetic field detection equipment used for reading of a semiconductor integrated for outputting chip information as a magnetic line of force.
